(19) United States
(12) Patent Application Publication
(10) Pub. No.: US 2024/0082951 A1
(43) Pub. Date: Mar. 14, 2024

(54) LASER PROCESSING MACHINE

(71) Applicant: DISCO CORPORATION, Tokyo (JP)

(72) Inventor: Naotoshi KIRIHARA, Tokyo (JP)

(21) Appl. No.: 18/452,756

(22) Filed: Aug. 21, 2023

(30) Foreign Application Priority Data
Sep. 8, 2022 (JP) 2022-143237

(51) Int. Cl. B23K 26/06; B23K 26/02; B23K 26/0622

(52) U.S. Cl. CPC B23K 26/0665; B23K 26/02; B23K 26/0622; B23K 2103/56

(57) ABSTRACT

A laser beam irradiation unit of a laser processing machine includes a laser oscillation unit that emits an initial pulsed laser beam, and a condenser that condenses the initial pulsed laser beam emitted by the laser oscillation unit and focuses a pulsed irradiation laser beam on a wafer having a silicon substrate and held on a chuck table. The laser oscillation unit is configured to oscillate a pulsed laser of deep ultraviolet light at a pulse interval shorter than a thermal diffusion time in an SiO₂ film stacked on an upper surface of the silicon substrate, and to emit the initial pulsed laser beam.

### BACKGROUND OF THE INVENTION

### Field of the Invention

The present invention relates to a laser processing machine that emits a pulsed laser beam.

### Description of the Related Art

A wafer with a plurality of devices such as integrated circuits (ICs) or large-scale integration (LSI) circuits formed isolated by a plurality of intersecting scribe lines on a front surface thereof is divided into individual device chips by a dicing machine or a laser processing machine, and the divided device chips are used in electronic equipment such as mobile phones or personal computers.

If a low dielectric constant insulation film called a “low-k film” is stacked on the front surface of the wafer, cutting of the wafer by a cutting blade causes the low-k film to delaminate like mica, and this delamination spreads from the scribe lines to the devices, thereby raising a problem that the devices are lowered in quality.

To prevent the delamination of the insulation film from spreading to the devices even when the wafer is cut along the scribe lines by the cutting blade, the assignee of the subject application has hence proposed a technology to apply a laser beam to both sides of each scribe line to form two lines of grooves and to cut the wafer between the two lines of grooves by the cutting blade (see JP 2005-064230A).

### SUMMARY OF THE INVENTION

If a low-k film (thickness: 10 μm) has been formed by stacking an SiO₂ film, however, there is a problem in that leak light of a laser beam causes delamination at an interface between the low-k film and a silicon substrate and lowers the quality of devices divided individually from a wafer. Improvements have therefore been demanded in the problem.

The present invention therefore has, as an object thereof, the provision of a laser processing machine which, even if a low-k film (thickness: 10 μm) has been formed by stacking an SiO₂ film, leak light of a laser beam is suppressed to cause no delamination at an interface between the low-k film and a silicon substrate.

In accordance with an aspect of the present invention, there is provided a laser processing machine including a chuck table that holds a wafer having a silicon substrate, a laser beam irradiation unit that applies a pulsed irradiation laser beam to the wafer held on the chuck table, and a feed mechanism that causes a relative processing feed of the chuck table and the laser beam irradiation unit. The laser beam irradiation unit includes a laser oscillation unit that emits an initial pulsed laser beam, and a condenser that condenses the initial pulsed laser beam emitted by the laser oscillation unit and focuses a pulsed irradiation laser beam on the wafer held on the chuck table. The laser oscillation unit is configured to oscillate a pulsed laser of deep ultraviolet light at a pulse interval shorter than a thermal diffusion time in an SiO₂ film stacked on an upper surface of the silicon substrate, and to emit the initial pulsed laser beam.

Preferably, the deep ultraviolet light is a laser beam having a wavelength of 266 nm or shorter, and the initial pulsed laser beam emitted by the laser oscillation unit has a pulse width of 200 fs, which corresponds to a smallest point of energy density, or shorter. Preferably, the laser beam irradiation unit is configured such that, when the initial pulsed laser beam emitted by the laser oscillation unit is applied as the pulsed irradiation laser beam, the pulsed irradiation laser beam has a pulse interval shorter than 1.0 μs that is the thermal diffusion time in the SiO₂ film.

According to the present invention, the suppression of leak light of the pulsed irradiation laser beam applied by the laser beam irradiation unit is feasible, thereby making it possible to solve the problem that delamination occurs at the interface between the low-k film formed by the SiO₂ film and the silicon substrate, when laser processing is performed.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is an overall perspective view of a laser processing machine according to an embodiment of the present invention;

FIG. 2 is a block diagram illustrating an optical system of a laser beam irradiation unit arranged in the laser processing machine of FIG. 1;

FIG. 3 is a concept diagram illustrating smallest points of processing thresholds from a relation between pulse width and energy density;

FIG. 4A is optical micrographs illustrating images of front surfaces of wafers at laser-processed positions corresponding to pulse intervals of pulsed laser beams;

FIG. 4B is a concept diagram illustrating how a low-k film is removed by laser processing;

FIG. 5 is a perspective view illustrating how laser processing is performed by the laser processing machine of the embodiment; and

FIG. 6 is an enlarged fragmentary cross-sectional view of the laser processing illustrated in FIG. 5.

### DETAILED DESCRIPTION OF THE PREFERRED EMBODIMENT

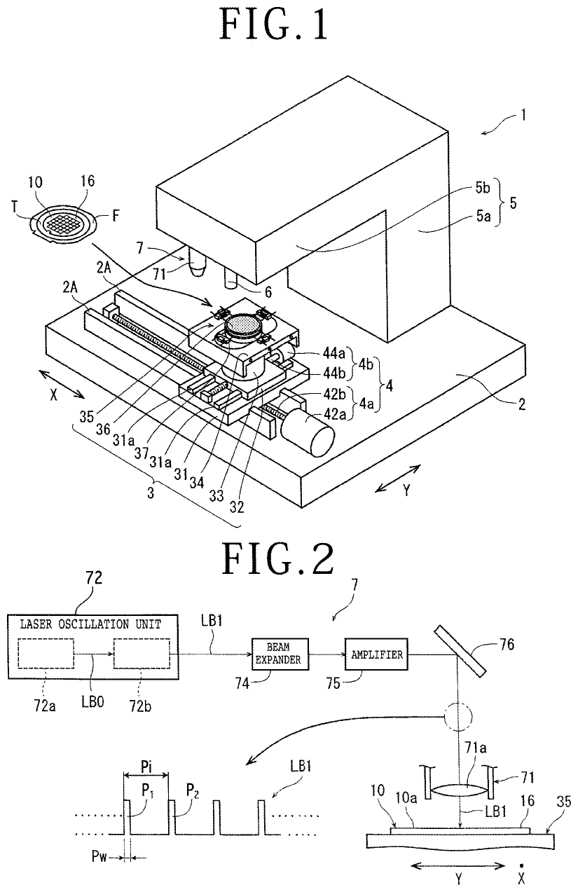

With reference to the attached drawings, a description will hereinafter be made in detail about a laser processing machine according to an embodiment of the present invention. FIG. 1 illustrates a laser processing machine 1 of the present embodiment. Using the laser processing machine 1, laser processing is applied to a wafer 10 held on an annular frame F via a self-adhesive tape T as illustrated in the figure, so that a laser beam is applied to both sides of each scribe line, which will be described subsequently herein, to form a processed groove including two lines of grooves. The wafer 10 has a silicon substrate 10c (see FIGS. 4B and 6), and a low-k film 16 of 10 μm thickness formed by stacking SiO₂ films on an upper surface of the silicon substrate 10c.

The laser processing machine 1 is arranged on a bed 2 and includes a holding unit 3 that holds the wafer 10, a laser beam irradiation unit 7 that applies a laser beam to the wafer 10, a feed mechanism 4 that causes a relative processing feed of the holding unit 3 and the laser beam irradiation unit 7, an alignment unit 6 that performs alignment by imaging the wafer 10 held on the holding unit 3, a column 5 constructed of a vertical base portion 5a disposed upright beside the feed mechanism 4 and a horizontal head portion 5b extending in a horizontal direction from an upper end portion of the vertical base portion 5a, and a controller, not illustrated, that controls individual working parts.

The holding unit 3 is means for holding the wafer 10 using, as a holding surface, an X-Y plane specified by an X-coordinate and a Y-coordinate, and, as illustrated in FIG. 1, includes a rectangular X-axis direction movable plate 31 mounted movably in an X-axis direction on the bed 2, a rectangular Y-axis direction movable plate 32 mounted movably in a Y-axis direction on the X-axis direction movable plate 31, a cylindrical post 33 fixed on an upper surface of the Y-axis direction movable plate 32, and a rectangular cover plate 34 fixed on an upper end of the post 33. On the cover plate 34, a chuck table 35 is arranged extending upwards through a slot formed in the cover plate 34. The chuck table 35 is configured to be rotatable by a rotary drive mechanism, not illustrated, accommodated in the post 33. On an upper surface of the chuck table 35, a circular suction chuck 36 is arranged. The suction chuck 36 is formed from a porous material having air permeability, and uses, as a holding surface, an X-Y plane specified by an X-coordinate and a Y-coordinate. The suction chuck 36 is connected to suction means, not illustrated, via a flow channel extending through the post 33, and around the suction chuck 36, four clamps 37 are arranged at equal intervals to grasp the annular frame F when holding the wafer 10 on the chuck table 35.

The feed mechanism 4 includes an X-axis moving mechanism 4a that moves the holding unit 3 in the X-axis direction, and a Y-axis moving mechanism 4b that moves the holding unit 3 in the Y-axis direction. The X-axis moving mechanism 4a converts rotary motion of a motor 42a into linear motion via a ball screw 42b, transmits the linear motion to the X-axis direction movable plate 31, and moves the X-axis direction movable plate 31 in the X-axis direction along a pair of guide rails 2A and 2A arranged along the X-axis direction on the bed 2. The Y-axis moving mechanism 4b converts rotary motion of a motor 44a into linear motion via a ball screw 44b, transmits the linear motion to the Y-axis direction movable plate 32, and moves the Y-axis direction movable plate 32 in the Y-axis direction along a pair of guide rails 31a and 31a arranged along the Y-axis direction on the X-axis direction movable plate 31.

Inside the horizontal head portion 5b of the column 5, an optical system, which constitutes the above-described laser beam irradiation unit 7, and the alignment unit 6 are accommodated. On a side of a lower surface of a distal end portion of the horizontal head portion 5b, a condenser 71 which constitutes a part of the laser beam irradiation unit 7 is arranged. The alignment unit 6 is imaging means for imaging the wafer 10 held on the holding unit 3 and detecting a position and direction of the wafer 10, a laser processing position to which a laser beam is to be applied, and the like, and is arranged at a position adjacent in the X-axis direction, which is indicated by an arrow X in the figure, to the above-described condenser 71.

FIG. 2 is a block diagram illustrating an outline of the optical system of the laser beam irradiation unit 7 in the present embodiment. The laser beam irradiation unit 7 includes a laser oscillation unit 72 that emits a pulsed laser beam LB1 of a desired wavelength, a beam expander 74 that expands the pulsed laser beam LB1 in diameter, an amplifier 75 that amplifies power, a reflection mirror 76 for changing an optical path, and the condenser 71 including a condenser lens 71a that condenses the pulsed laser beam LB1 emitted by the laser oscillation unit 72 and focuses it on the wafer 10 held on the holding unit 3. The laser oscillation unit 72 in the present embodiment includes a laser oscillator 72a that emits a pulsed laser beam LB0 of 532 nm wavelength and a wavelength converter 72b (for example, a BaB₂O₄ (BBO) crystal, a calcium lead borate (CLBO) crystal, or the like) that converts the pulsed laser beam LB0, which has been emitted from the laser oscillator 72a, into the pulsed laser beam LB1. The beam expander 74 protects the optical system, which terminates in the condenser 71, by expanding the diameter of the pulsed laser beam LB1. It is to be noted that a concept diagram of the pulsed laser beam LB1, which is to be applied by the laser beam irradiation unit 7, is illustrated in FIG. 2, and that a pulse width Pw and a pulse interval Pi are indicated by successive pulses P₁ and P₂.

For the laser processing to be performed by the laser processing machine 1 of the present embodiment, laser processing conditions are set such that, when removing the low-k film 16, which is stacked on an upper surface of the wafer 10, to form processed grooves by applying the pulsed laser beam LB1, leak light of the pulsed laser beam LB1 is suppressed to prevent occurrence of delamination at an interface between the low-k film 16 and the silicon substrate constituting the wafer 10. A description will hereinafter be made about results of study and experimentation conducted by the inventor of the present invention when setting the laser processing conditions.

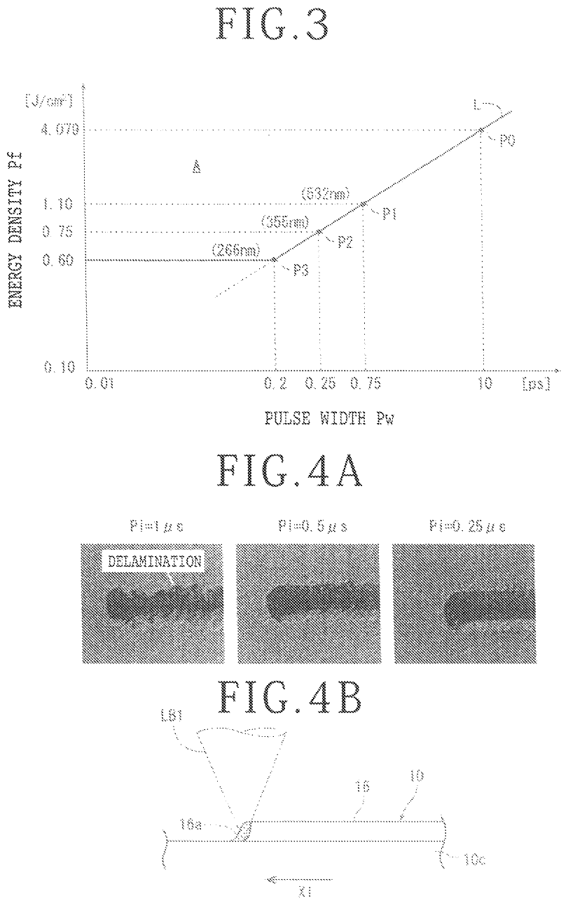

The inventor of the present invention first studied processing thresholds of energy density Pf and pulse width Pw, at which the SiO₂ film that forms the low-k film 16 can be removed, according to the wavelength of a pulsed laser beam applied by the laser beam irradiation unit 7. In FIG. 3, pulse width PW [ps] is plotted along the abscissa, energy density Pf [J/cm²] is plotted along the ordinate, and an upper region A bounded by a processing threshold straight line L indicates a region indicating conditions under which the low-k film 16 formed on the upper surface of the wafer 10 can be removed.

In FIG. 3, for example, if a point P0 on the processing threshold straight line L, in other words, the pulse width Pw is 10 μs, it is indicated that processing is feasible at an energy density Pf of 4.079 J/cm² or higher. If green light of 532 nm wavelength is selected as the pulsed laser beam LB1, the processing thresholds fall at a smallest point P1 indicating a processing limit value at a pulse width Pw of 0.75 μs and an energy density Pf of 1.10 J/cm². It is therefore understood that, if the pulse width Pw is set at a value greater than the limit pulse width (=0.75 μs) corresponding to the smallest point P1 of the energy density Pf, the low-k film 16 cannot be processed unless the energy density Pf is adjusted to a value greater than 1.10 J/cm² so as to make it fall within the above-described region A. If the wavelength of the pulsed laser beam is made shorter to 355 nm (ultraviolet light) and further to 266 nm (deep ultraviolet light) as illustrated in FIG. 3, the pulse width Pw becomes shorter to 0.25 μs and further to 0.2 μs (=200 fs) corresponding to smallest points P2 and P3, respectively, of energy density as the processing thresholds at the respective wavelengths, thereby making it possible to perform the processing with smaller energy. From the above-described results of study, it is hence understood that, if a short pulse width that makes it possible to increase the energy density, specifically, the peak power density is selected to lower the energy of leakage light when the pulsed laser beam LB1 is applied to the low-k film 16, selection of a pulsed laser beam of deep ultraviolet light (wavelength: 100 to 280 nm) is preferred, and selection of deep ultraviolet light of 266 nm or shorter wavelength is more preferred.

The inventor of the present invention also has found that, as the low-k film 16 stacked on the wafer 10 is formed by stacking the SiO₂ film and the thermal diffusion time in SiO₂ is 1.0 μs, the prevention of occurrence of delamination at the interface between the low-k film 16 and the silicon substrate needs to set the pulse interval Pi of the pulsed laser beam LB1, which is to be applied to the low-k film 16 by the laser beam irradiation unit 7, at a repetition frequency of an interval shorter than the thermal diffusion time (1.0 μs), specifically at a repetition frequency greater than 1 MHz. On the basis of the above-described finding, the inventor of the present application conducted a laser processing experiment while varying the repetition frequency to 1 MHz, 2 MHz, and 4 MHz when the pulse laser beam LB1 is emitted by the laser oscillation unit 72 and also varying the feed rate to 100 mm/s when the repetition frequency was 1 MHz, 200 mm/s when the repetition frequency was 2 MHz, and 400 m/s when the repetition frequency was 4 MHz, respectively, such that the spot interval remained constant (0.1 μm) at every repetition frequency.

As a result, as understood from FIG. 4A that illustrates individual images of front surfaces at laser-processed positions, it has been confirmed that the processing quality is progressively improved as the pulse interval Pi of the pulsed laser beam L1 becomes shorter in the order of 1.0 μs, 0.5 μs, and 0.25 μs, and that the delamination at a position applied by the pulsed laser beam LB1 is suppressed after the pulse interval Pi decreases to smaller than 1.0 μs that is the thermal diffusion time in the SiO₂ film. This indicates that the setting of the pulse interval Pi of the pulsed laser beam LB1, which is repeatedly applied while a processing feed of the wafer 10 is caused in a direction indicated by an arrow X1 as illustrated in FIG. 4B, at an interval shorter than the thermal diffusion time in the SiO₂ film allows the low-k film 16, which has been formed by stacking the SiO₂ film, to absorb the pulsed laser beam LB1 when it is in a liquid phase state 16a and hence can prevent the delamination at the interface between the low-k film 16 and the silicon substrate 10c.

From the foregoing, it has been found that the setting of the laser oscillation unit 72, which is arranged in the laser beam irradiation unit 7 in the present embodiment, so as to emit the pulsed laser beam LB1 of deep ultraviolet light at a pulse interval Pi shorter than the thermal diffusion time (1.0 μs) in the SiO₂ film constituting the low-k film 16 of the wafer 10 makes it possible to suppress the leakage light of the pulsed laser beam LB1 applied by the laser beam irradiation unit 7 and also solves the problem that the low-k film 16 is removed and delamination is caused at the interface with the silicon substrate 10c.

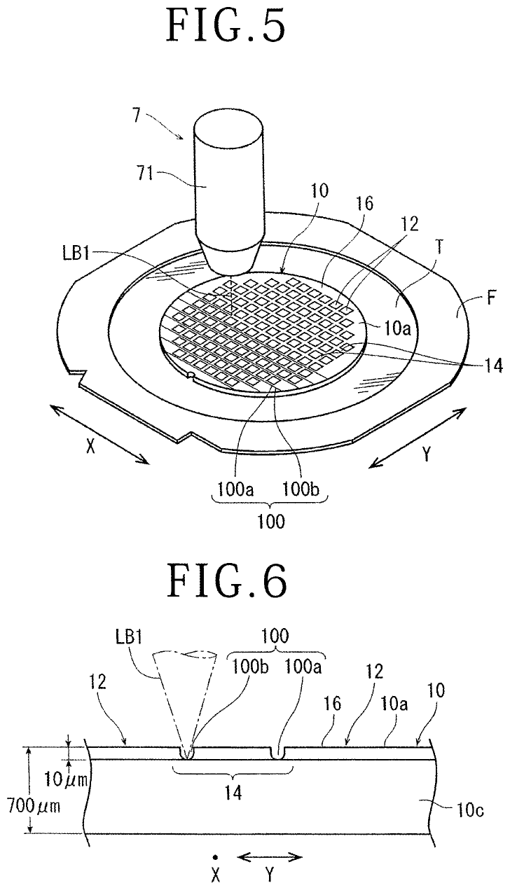

With reference to FIGS. 1, 5, and 6, the laser processing to be performed by the laser processing machine 1 of the present embodiment will be described more specifically. As illustrated in FIG. 5, the wafer 10 to be processed by the laser processing machine 1 of the present embodiment is held on the annular frame F via the self-adhesive tape T. The wafer 10 has a plurality of devices 12 formed on a front surface 10a thereof and isolated by scribe lines 14, and has the low-k film 16 formed and arranged by stacking the SiO₂ film on the upper surface of the wafer 10. The low-k film 16 has a thickness of 10 μm, and the wafer 10 has a total thickness of 700 μm (for the sake of convenience of description, however, these thicknesses are not at an actual dimensional ratio).

In the laser processing to be described hereinafter, processing is performed to form two lines of grooves 100a and 100b on both sides of each scribe line 14 by applying the pulsed laser beam LB1 and removing the low-k film 16. When the laser processing is performed on the above-described wafer 10, the wafer 10 is transferred to the laser processing machine 1 described on the basis of FIG. 1 and is held under suction on the chuck table 35 of the holding unit 3, and the annular frame F is fixed by the clamps 37. The wafer 10 held on the holding unit 3 is then transferred to right below the alignment unit 6 by the feed mechanism 4, and alignment is performed to detect the positions of the scribe lines 14 formed on the front surface 10a. Next, the wafer 10 is rotated by the rotary drive mechanism to bring the scribe lines 14 which extend in a first direction, into alignment with the X-axis direction. Information on the positions of the scribe lines 14 as detected above is stored in the controller, not illustrated.

On the basis of the information on the positions detected by the above-described alignment, the condenser 71 of the laser beam irradiation unit 7 is positioned right above a predetermined processing start position on desired one of the scribe lines 14 extending in the first direction. The laser processing by the laser processing machine 1 of the present embodiment is to form the two lines of grooves 100a and 100b along both sides of the desired scribe line 14 as described above. Therefore, the pulsed laser beam LB1 is applied with its focal point positioned at a predetermined position on the desired scribe line 14 formed on the front surface 10a of the wafer 10, and, at the same time, the above-described feed mechanism 4 is actuated to cause a processing feed of the wafer 10 along with the holding unit 3 in the X-axis direction. As illustrated in FIG. 6, after the groove 100a has been formed extending in the X-axis direction from the predetermined position in the desired scribe line 14, the wafer 10 is fed for indexing in the Y-axis direction by a width needed for the formation of the two lines of grooves 100a and 100b, and the groove 100b similar to the above-described groove 100a is then formed. As a result, a processed groove 100 is formed including the two lines of grooves 100a and 100b along both sides of the desired scribe line 14 extending in the first direction on the wafer 10. After the processed groove 100 has been formed along the desired scribe line 14, the wafer 10 is fed for indexing in the Y-axis direction, and the unprocessed scribe line 14, which is adjacent in the Y-axis direction to the processed desired scribe line 14, is positioned right below the condenser 71. In a similar manner to the above, the pulsed laser beam LB1 is applied with its focal point positioned at a predetermined position on the adjacent scribe line 14, and the wafer 10 is then fed for processing in the X-axis direction to form another processed groove 100 similar to the above-described processed groove 100. While a processing feed of the wafer 10 is caused in the X-axis direction and also in the Y-axis direction, processed grooves 100 are formed along all the scribe lines 14 that extend along the first direction.

The wafer 10 is next rotated 90 degrees, so that the unprocessed scribe lines 14, which extend in a second direction orthogonal to the scribe lines 14 extending in the first direction and having already been formed with the processed grooves 100, are brought into alignment with the X-axis direction. To each remaining unprocessed scribe line 14, the pulsed laser beam LB1 is then applied with its focal point positioned at a predetermined position in a similar manner to the above, whereby processed grooves, each including two lines of grooves 100a and 100b, are formed along all the scribe lines 14 formed on the front surface 10a of the wafer 10.

On the basis of the above-described results of study and experimentation, the laser processing conditions for performing laser processing by the laser processing machine 1 of the present embodiment may be set in the following ranges.
Wavelength: 100 to 280 nm (preferably, 266 nm or shorter)
Repetition frequency: 1 MHz or greater (pulse interval: smaller than 1.0 μs)
Average power: 0.8 W
Pulse width: 200 fs or smaller
Processing feed rate: 100 mm/s or higher
Numerical aperture (NA): 0.068

Under the above-described laser processing conditions, the wavelength of the pulsed laser beam LB1 to be emitted by the laser beam irradiation unit 7 is selected from the wavelength range (100 to 280 nm) called “deep ultraviolet light,” and the repetition frequency is set in a range greater than 1 MHz, in which the pulse interval of the pulsed laser beam LB1 is shorter than the thermal diffusion time (1.0 μs) in the SiO₂ film that constitutes the low-k film 16. These settings make it possible to suppress the leakage light of the pulsed laser beam LB1 applied by the laser beam irradiation unit 7. It has been therefore possible to form the grooves 100a and 100b by removing the low-k film 16 while suppressing the delamination at the interface between the low-k film 16 and the silicon substrate 10c.

In particular, by selecting deep ultraviolet light of 266 nm wavelength for the pulsed laser beam LB1 and setting the pulse width Pw of the pulsed laser beam LB1, which is to be emitted by the laser oscillation unit 72, at 200 fs corresponding to the above-described smallest point P3 of energy density, the above-described advantageous effects can be ensured to be available. It is to be noted that, on the basis of the results of study as described above on the basis of FIG. 3, advantageous effects similar to those described above can be obtained by selecting deep ultraviolet light of 266 nm or shorter wavelength as the deep ultraviolet light to be selected as the pulsed laser beam LB1 and also by selecting a pulse width of 200 fs, which corresponds to the smallest point of the energy density at the selected wavelength, or smaller.

The present invention is not limited to the details of the above-described preferred embodiment. The scope of the invention is defined by the appended claims and all changes and modifications as fall within the equivalence of the scope of the claims are therefore to be embraced by the invention.

What is claimed is:

1. A laser processing machine comprising:
a chuck table that holds a wafer having a silicon substrate;
a laser beam irradiation unit that applies a pulsed irradiation laser beam to the wafer held on the chuck table; and
a feed mechanism that causes a relative processing feed of the chuck table and the laser beam irradiation unit, wherein
the laser beam irradiation unit includes a laser oscillation unit that emits an initial pulsed laser beam, and a condenser that condenses the initial pulsed laser beam emitted by the laser oscillation unit and focuses a pulsed irradiation laser beam on the wafer held on the chuck table, and
the laser oscillation unit is configured to oscillate a pulsed laser of deep ultraviolet light at a pulse interval shorter than a thermal diffusion time in an SiO₂ film stacked on an upper surface of the silicon substrate, and to emit the initial pulsed laser beam.

2. The laser processing machine according to claim 1, wherein the deep ultraviolet light is a laser beam having a wavelength of 266 nm or shorter, and the initial pulsed laser beam emitted by the laser oscillation unit has a pulse width of 200 fs, which corresponds to a smallest point of energy density, or shorter.

3. The laser processing machine according to claim 1, wherein the laser beam irradiation unit is configured such that, when the initial pulsed laser beam emitted by the laser oscillation unit is applied as the pulsed irradiation laser beam, the pulsed irradiation laser beam has a pulse interval shorter than 1.0 μs that is the thermal diffusion time in the SiO₂ film.
